(19) United States
(12) Patent Application Publication
(10) Pub. No.: US 2006/0022854 A1
(43) Pub. Date: Feb. 2, 2006

(54) Method and apparatus for operating correlator of an ADC circuit

(76) Inventor: Johnny Bjornsen, Trondheim (NO)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/191,819

(22) Filed: Jul. 28, 2005

Related U.S. Application Data
(60) Provisional application No. 60/592,718, filed on Jul. 29, 2004.

(51) Int. Cl. H03M 1/10

(52) U.S. Cl. 341/120

(57) ABSTRACT

An analog-to-digital converter (ADC) circuit that converts an analog input signal into a digital output circuit includes a reduced block length correlator circuit and a digital subtractor circuit, where the digital subtractor circuit subtracts digital output of a calibrated stage of the ADC circuit from an overall output of the ADC circuit, and feeds the result of the subtraction to correlator circuit, reducing the magnitude of an input signal seen by the correlator and thereby increasing the signal to noise ratio (SNR) and the accuracy of the correlator. The ADC circuit also provides significant reduction of block length, die area and power dissipation related to the correlator.

### CROSS-REFERENCES TO RELATED APPLICATIONS

This application claims priority to U.S. Provisional Application Ser. No. 60/592,718, entitled, “Method and Apparatus for Operating a Correlator of an Analog-to-Digital Converter Circuit,” filed Jul. 29, 2004, the disclosure of which is hereby expressly incorporated herein by reference.

### TECHNICAL FIELD

This patent relates generally to analog-to-digital converters, and more specifically to an apparatus and a method for operating a correlator of an analog-to-digital converter circuit.

### BACKGROUND

Analog-to-digital converters (ADCs) are employed in a variety of electronic systems including computer modems, wireless telephones, satellite receivers, process control systems, etc. Such systems demand cost-effective ADCs that can efficiently convert an analog input signal to a digital output signal over a wide range of frequencies and signal magnitudes with minimal noise and distortion.

An ADC typically converts an analog signal to a digital signal by sampling the analog signal at pre-determined sampling intervals and generating a sequence of binary numbers via a quantizer, wherein the sequence of binary numbers is a digital representation of the sampled analog signal. Some of the commonly used types of ADCs include integrating ADCs, Flash ADCs, pipelined ADCs, successive approximation register ADCs, Delta-Sigma (ΔΣ) ADCs, two-step ADCs, etc. Of these various types, the pipelined ADCs and the ΔΣ ADCs are particularly popular in applications requiring-higher resolutions.

A pipelined ADC circuit samples an analog input signal using a sample-and-hold circuit to hold the input signal steady and a first stage flash ADC to quantize the input signal. The first stage flash ADC then feeds the quantized signal to a digital-to-analog converter (DAC). The pipelined ADC circuit subtracts the output of the DAC from the analog input signal to get a residue signal of the first stage. The first stage of the pipelined ADC circuit generates the most significant bit (MSB) of the digital output signal. The residue signal of the first stage is gained up by a factor and fed to the next stage. Subsequently, the next stage of the pipelined ADC circuit further quantizes the residue signal to generate further bits of the digital output signal.

On the other hand, a ΔΣ ADC employs over-sampling, noise-shaping, digital filtering and digital decimation techniques to provide high resolution analog-to-digital conversion. One popular design of a ΔΣ ADC is multi-stage noise shaping (MASH) ΔΣ ADC. A MASH ΔΣ ADC is based on cascading multiple first-order or second-order ΔΣ ADCs to realize high-order noise shaping. An implementation of a MASH ΔΣ ADC is well known to those of ordinary skill in the art. While both pipelined ADCs and ΔΣ ADCs provide improved signal-to-noise ratio, improved stability, etc., ΔΣ ADCs generally provide higher levels of resolution and therefore are preferred in applications involving asynchronous digital subscriber lines (ADSL), very high speed digital subscriber lines (VDSL), etc. Highly-linear, high-resolution and wide-bandwidth ADCs are required for VDSL systems.

Both pipelined and ΔΣ ADCs use digital calibration of gain errors to achieve low power dissipation and high performance. One type of calibration method used by ADCs involves inserting a pseudo-random test signal at the input of a stage of ADC to be calibrated. Such test signal based calibration can be applied to both pipelined and ΔΣ ADCs.

FIG. 1 is a block diagram of a gain calibrated pipelined ADC 10. The ADC 10 includes a first stage 12 including the blocks labeled ADC₁, DAC₁ and the gain stage (2x), while the remaining stages are hidden in a second 14 block labeled ADC₂. The ADC 10 includes a calibration filter 16 for calibrating the ADC 10. The calibration filter 16 operates on the output d₂(k) of the second stage 14, while observing the recombined ADC output dg(k). A digital dither generator 18 generates a two-level random signal ts(k) that is digitally added to the input of the first stage 12 by means of DAC I. This dither signal is also used for the calibration filter 16.

FIG. 2 is a block diagram of a calibrated pipelined ADC 20 with a first stage 22 having m bit resolution and the backend stages, referred to by a second stage 24 having b bit resolution, resulting in N bit resolution of the recombined output y. The ADC 20 includes a calibration filter 26, which consists of a digital multiplier with coefficient 1+l₀. A correlator 28 consisting of a multiplier 30, an accumulator 32 and a digital quantizer Q 34 is used for determining the coefficient for the calibration filter 26.

FIG. 3 illustrates a block diagram of a MASH AZ ADC 40 that is continuously calibrated for gain errors. The ADC 40 includes a first stage 42 having a dithering/noise shaping filter L(z), a DAC, ADC₁ and the multiplier a₁, and the remaining stages referred to by a second stage 44 and denoted by ADC₂. The ADC 40 also includes a calibration filter 46 that operates on the output of the second stage 44 while observing the recombined output y of the ADC 40. The filters H₁(z) and H₂(z) are necessary for correct recombination of the digital outputs d₁(k) and d_{c}(k) in such a way that the quantization error from the first stage 42 is not visible in the recombined output y.

FIG. 4 illustrates a block diagram of a MASH ΔΣ ADC 50 which is similar to the ADC 40 shown in FIG. 3, with additional details of the calibration filter 46, and the other filters H₁(z) and H₂(z) is shown. The dithering/noise shaping filter L(z) is replaced by a block having a transfer function of G/(1−pz⁽⁻¹⁾), while the calibration filter 46 consists of two digital multipliers with coefficients l₀ and l₁. The ADC 50 also includes a correlator 52 consisting of two digital multipliers, two accumulators and two digital quantizers determining the sign of the accumulators. The correlator 52 of the MASH ΔΣ ADC 50 operates on the recombined output y of the ADC 50.

A disadvantage with the implementation of the calibration filters as shown in FIG. 2 for a pipelined ADC, as well as the one shown in FIG. 4 for a MASH ΔΣ ADC is the long time constant related to the update of the calibration filter coefficients. Such a long time constant is necessary to ensure high accuracy of the calibration filter coefficient values. Generally, each of the correlators used in FIGS. 2 and 4 are implemented using a digital multiplier and an accumulator. Another drawback with the long block lengths of such correlators is that the bit width of the accumulator becomes excessively long, resulting in high die area and power dissipation related to the digital implementation of this accumulator.

### BRIEF DESCRIPTION OF THE DRAWINGS

The present patent is illustrated by way of examples and not limitations in the accompanying figures, in which like references indicate similar elements, and in which:

FIG. 1 is a block diagram of a gain calibrated pipelined ADC;

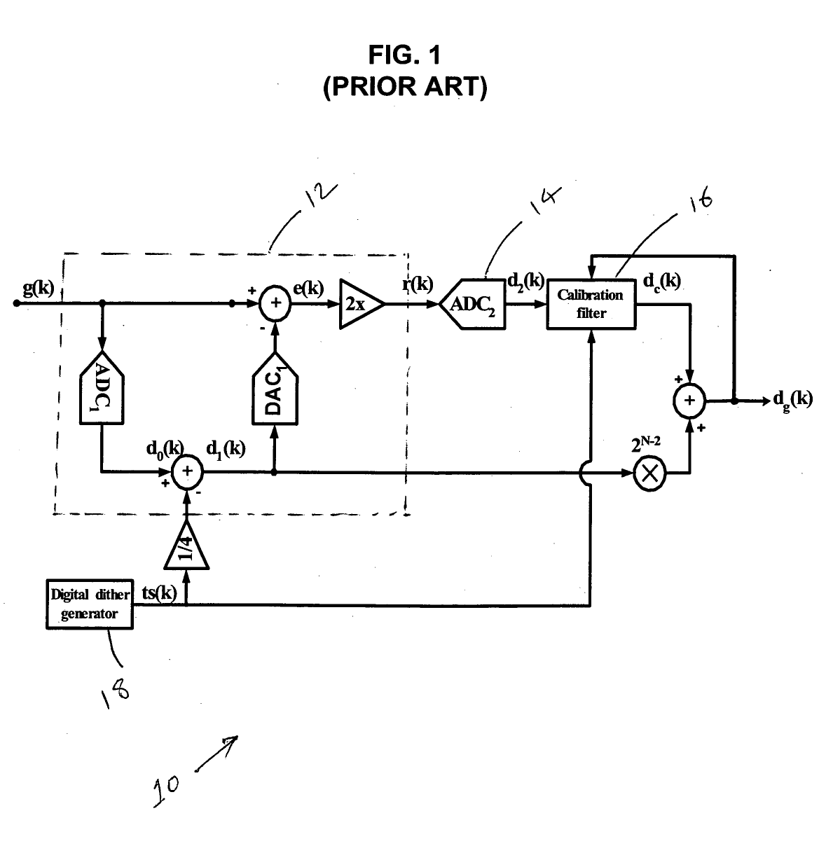

FIG. 2 is a block diagram of a calibrated pipelined ADC of FIG. 1 having a correlator;

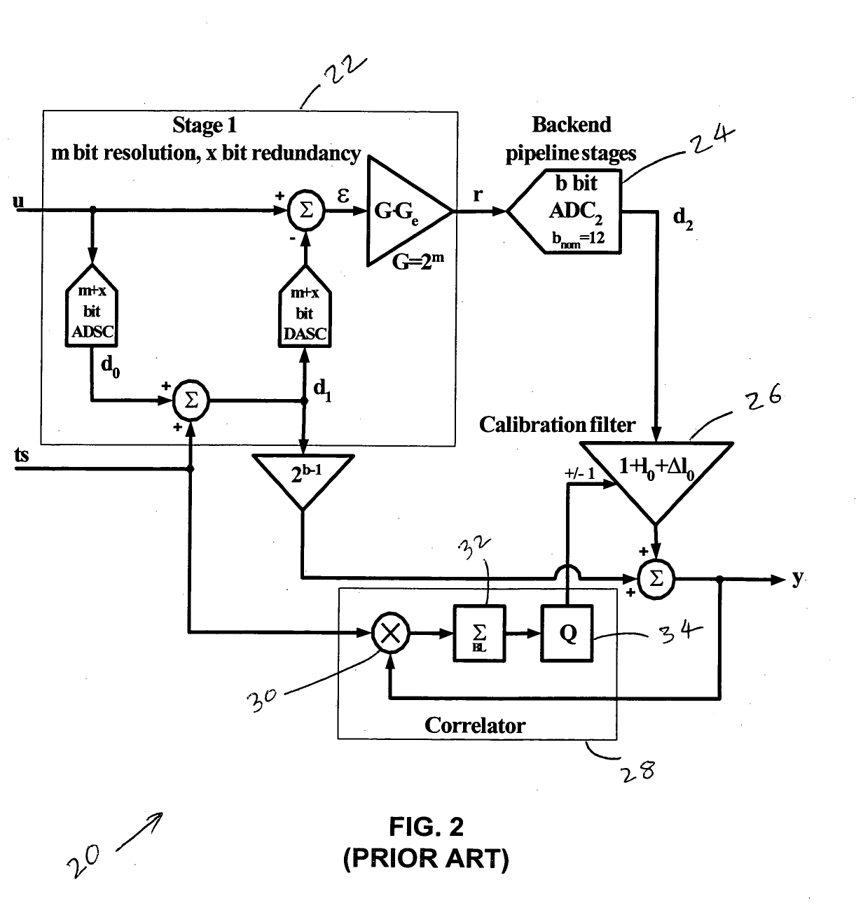

FIG. 3 is block diagram of a MASH AZ ADC;

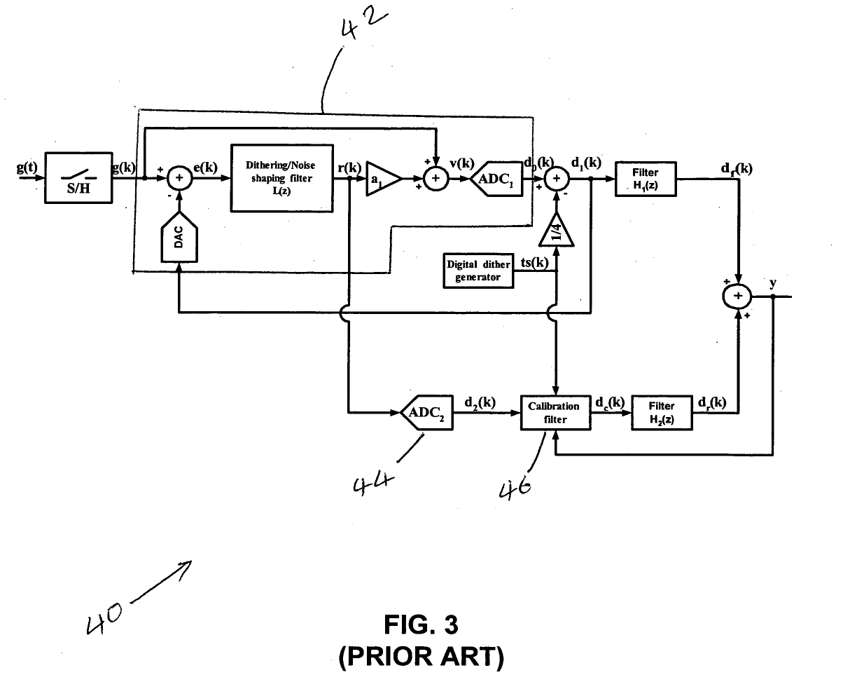

FIG. 4 is a block diagram of a MASH AZ ADC as shown in FIG. 3 having a correlator;

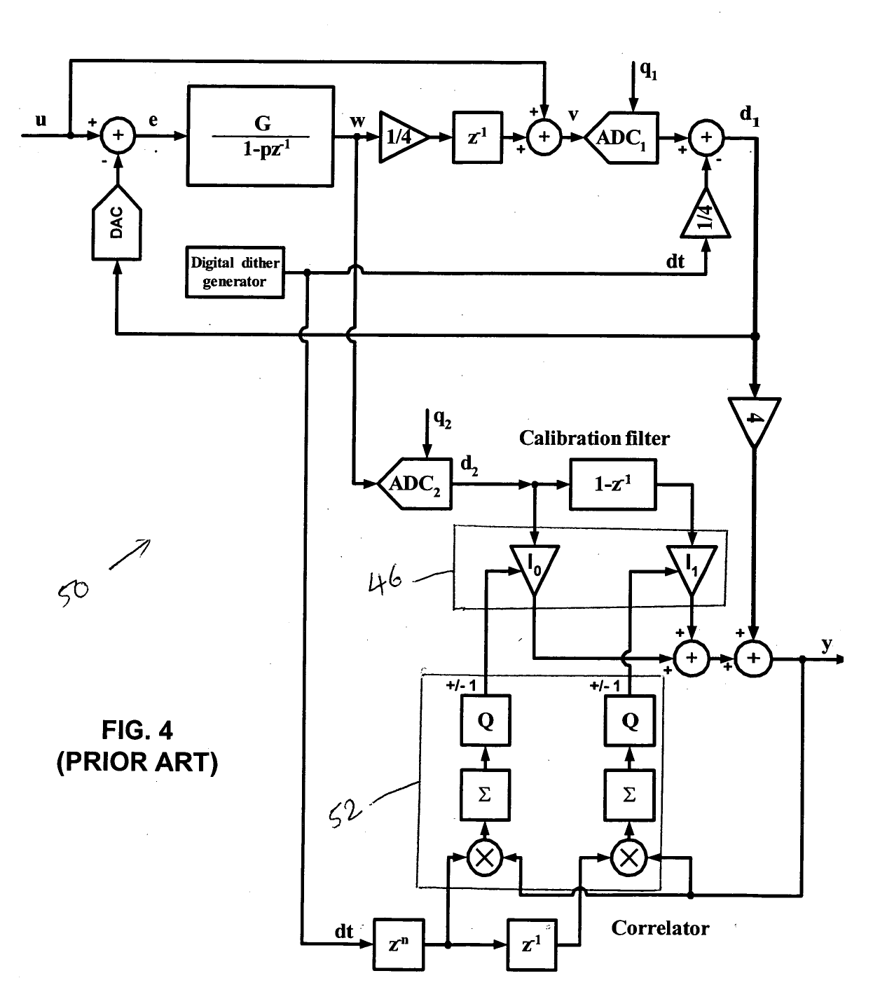

FIG. 5 is a block diagram of a pipelined ADC having a reduced block length correlator; and

FIG. 6 is a block diagram of a MASH AZ ADC having a reduced block length correlator.

### DETAILED DESCRIPTION OF THE EXAMPLES

An analog-to-digital converter (ADC) circuit that converts an analog input signal into a digital output signal includes a reduced block length correlator circuit and a digital subtractor circuit, where the digital subtractor circuit subtracts the digital output of a calibrated stage of the ADC circuit from an overall output of the ADC circuit, and feeds the result of the subtraction to the correlator circuit, reducing the magnitude of an input signal seen by the correlator and thereby increasing the signal to noise ratio (SNR) and the accuracy of the correlator. The ADC circuit also provides significant reduction of block length, die area and power dissipation related to the correlator. Compared to a standard ADC circuit, the ADC circuit having the modified correlator circuit also provides significant reduction in block length, die area and power dissipation.

An embodiment of the ADC system for converting an analog input signal to a digital output signal comprises a first stage analog-to-digital converter circuit adapted to generate a residue signal based on the analog input signal, a backend stage analog-to-digital converter circuit adapted to generate the digital output signal based on the residue signal, a dither signal generator adapted to generate a dither signal to be inputted to the first stage analog-to-digital converter circuit, a correlator circuit adapted to determine traces of the dither signal in the digital output signal, and a calibration filter adapted to remove the traces of the dither signal from the digital output signal.

An alternate embodiment of the ADC system further comprises a scaling circuit adapted to receive a quantized output signal from the first stage of the analog-to-digital circuit and to generate a scaled quantized signal to be input to the correlator circuit. In an alternate embodiment of the ADC system, the scaling circuit is further adapted to scale the quantized output signal from the first stage by a scaling factor of 2b-1 wherein b is a resolution of a backend stage of the analog-to-digital converter circuit.

In yet another alternate embodiment of the ADC system, the correlator circuit further comprises a subtractor circuit adapted to subtract the scaled quantized signal from the digital output signal, a multiplier circuit adapted to multiply the output of the subtractor circuit, an accumulator circuit adapted to accumulate the output of the multiplier circuit and a re-quantizer circuit adapted to generate a 1 bit output signal based on the output of the accumulator circuit.

An alternate embodiment of the ADC system further comprises a calibration circuit adapted to calibrate the output of the backend stage of the analog-to-digital converter circuit based on the output of the correlator circuit. In an alternate embodiment of the ADC system, the first stage analog-to-digital converter circuit and the backend analog-to-digital converter circuit are ΔΣ analog to digital converter circuits. In yet another alternate embodiment of the ADC system, the first stage analog-to-digital converter circuit and the backend analog-to-digital converter circuit are MASH ΔΣ analog to digital converter circuits.

An alternate embodiment of the ADC system comprises a quantization signal generator module adapted to generate a coarse quantization signal from the input signal, a differentiator module adapted to generate a difference signal based on the digital output signal and the coarse quantization signal, a multiplier module adapted to multiply the difference signal with the test signal to generate a product signal, an accumulator module adapted to accumulate the product signal and a detection module adapted to detect the sign at the output of the accumulator to determine the trace of the test signal.

In an alternate embodiment of the ADC system, the detector module is further adapted to re-quantize the accumulated signal to generate a one bit output signal. In yet another alternate embodiment of the ADC system, the quantization signal generator module is further adapted to scale a digital output of a first stage of the analog-to-digital converter circuit by a scaling factor. In yet another alternate embodiment of the ADC system, the scaling factor is equal to 2b-1 wherein b is a resolution of a backend stage of the analog-to-digital converter circuit.

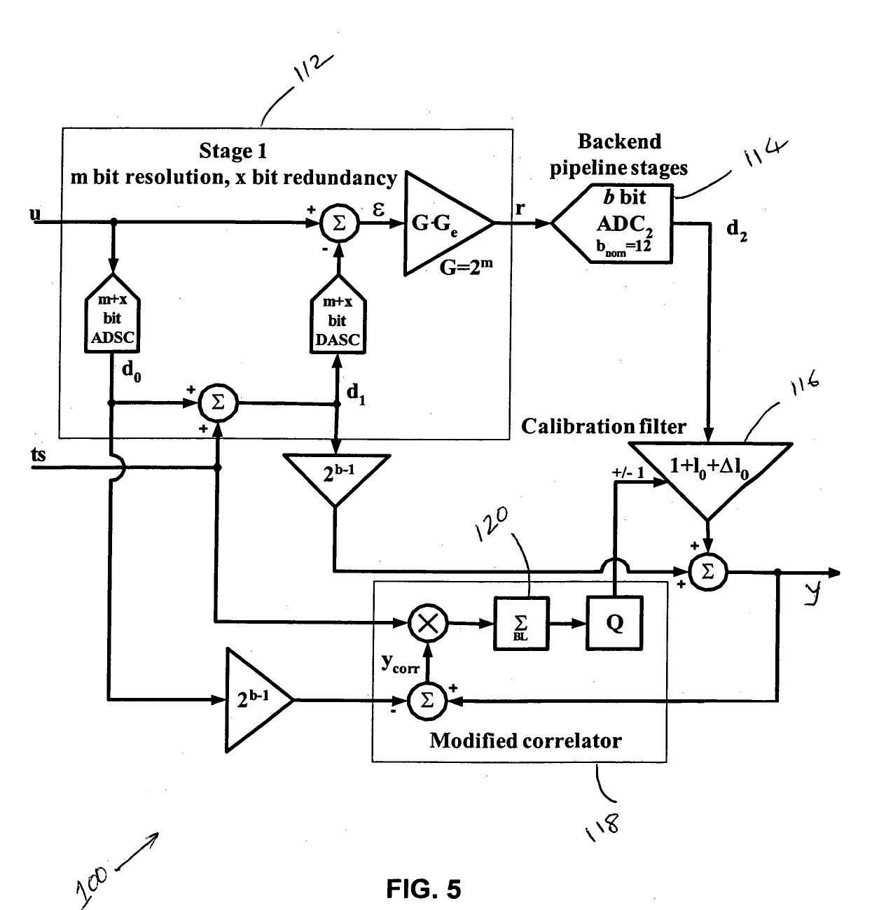

Specifically, FIG. 5 illustrates a block diagram of a pipelined ADC 100 having a first stage 112 having m bit resolution and backend stages having b bit resolution and represented by a second stage 114. The ADC 100 also includes a calibration filter 116 and a correlator 118. The correlator 118 includes a reduced block length accumulator 120, thereby resulting in reduced power dissipation within the ADC 100. The correlator 118 generates a corrected signal y_{corr} by subtracting the digital output d0 of a first stage ADSC scaled with a factor 2b-1 from a recombined output y of the ADC 100. This subtraction has the effect of allowing for a significant reduction in the block length of the correlator as shown below.

Define the input signal to the correlator ycorr. According to the block diagram in FIG. 5, ycorr can be calculated as:

$$\begin{matrix}ycorr = y - {d}_{0} {2}^{b - 1} \\ = u {2}^{m + b} + ( {q}_{1} + {t}_{s} ) \cdot {2}^{b - 1} ( 1 - Ge ( 1 + {l}_{0} + Δ {l}_{0} ) ) + \\ {q}_{2} ( 1 + {l}_{0} + Δ {l}_{0} ) - ( u {2}^{m + 1} + {q}_{1} ) {2}^{b - 1} \\ = - u {2}^{m + 1} {2}^{b - 1} + u {2}^{m + b} - {q}_{1} {2}^{b - 1} + {q}_{1} {2}^{b - 1} ( 1 - Ge ( 1 + {l}_{0} + Δ {l}_{0} ) ) + \\ ts {2}^{b - 1} ( 1 - Ge ( 1 + {l}_{0} + Δ {l}_{0} ) ) + {q}_{2} ( 1 + {l}_{0} + Δ {l}_{0} ) \\ = - {q}_{1} {2}^{b - 1} + {q}_{1} {2}^{b - 1} ( 1 - Ge ( 1 + {l}_{0} + Δ {l}_{0} ) ) + \\ ts {2}^{b - 1} ( 1 - Ge ( 1 + {l}_{0} + Δ {l}_{0} ) ) + {q}_{2} ( 1 + {l}_{0} + Δ {l}_{0} )\end{matrix}$$

Near perfect calibration, the terms with 1−Ge(1+l₀) are zero. Therefore, the expression above simplifies to
ycorr=−q₁2^{b-1}+q₁2^{b-1}GeΔl₀+ts2^{b-1}GeΔl₀+q₂ (1+l₀+Δlₒ).

Define the factor BL as the correlator block length, which equals the number of samples accumulated before the filter coefficient in FIG. 5 is updated.

Also, define a zero-mean two-level random signal Ts(n) with amplitude 1 which is perfectly correlated with the dither signal ts(n) so that their signs are always equal. It can be shown that the power of Ts(n) equals σ_{Ts}²=1.

Now the contents of the accumulator after a complete block length equals

$${y}_{Acc} = {\sum }_{0}^{BL} {y}_{corr} ( n ) \cdot Ts ( n ) .$$

The correlator 118 tries to detect the sign of the ts(n) signal in the recombined ADC output y. Define the factors S_{Acc}²=Signal power of the dither signal at the correlator 118 output, and Nₓ²=power of the noise components x,x=u, q1 or q2, at the correlator 118 output. Also, define Aₜₛ=amplitude of ts. The power of the signal the correlator 118 tries to detect is now given by

$$\begin{matrix}{S}_{Acc}^{2} = E \{ {( {\sum }_{0}^{BL - 1} Δ {l}_{0} {2}^{b - 1} Ge \cdot ts ( n ) \cdot Ts ( n ) )}^{2} \} \\ = {( Δ {l}_{0} {2}^{b - 1} Ge \cdot {\sum }_{0}^{BL - 1} E ( ts ( n ) \cdot Ts ( n ) ) )}^{2}\end{matrix}$$

Since the dither signal ts(n) is a two-level deterministic signal with known amplitude and sign, the expected value of the product of ts(n) and Ts(n) is simply the known value of the product. Also, since ts(n) and Ts(n) always have the same sign, and the amplitude of Ts(n) equals 1, the product in the above equation returns the absolute value of ts(n). The amplitude of the dither signal ts(n) is ¼ in this context. Therefore, the power of the ts signal in the accumulator is

$${S}_{Acc}^{2} = Δ {l}_{0}^{2} {2}^{2 {(}^{b - 1 )}} {Ge}^{2} \cdot {BL}^{2} {A}_{ts}^{2} = Δ {l}_{0}^{2} {2}^{2 {(}^{b - 1 )}} {Ge}^{2} \cdot {{BL}^{2} ( \frac{1}{4} )}^{2} .$$

The power stemming from the quantization noise q₁2^{b-1} of the first stage ADSC can be shown to be

$$\overline{{N}_{q {1}_{2}^{b - 1}}^{2}} = {BL ( {2}^{b - 1} )}^{2} \frac{1}{12}$$

This noise will dominate all the other noise sources in the correlator 118, and the SNR at the correlator 118 output can be found as

$$SNR = 10 {log}_{10} ( \frac{{S}_{Acc}^{2}}{\overline{{N}_{q {1}_{2}^{b - 1}}^{2}} + \overline{{N}_{q 1 Δ {l}_{0}}^{2}} + \overline{{N}_{q 2}^{2}}} ) \approx 10 {log}_{10} ( \frac{{S}_{Acc}^{2}}{\overline{{N}_{q {12}^{b - 1}}^{2}}} ) .$$

Inserted values for S_{Acc}² and Nₓ², the expression for SNR at the correlator 118 output now becomes

$$SNR = 10 {log}_{10} ( \frac{Δ {l}_{0}^{2} {2}^{2 {(}^{b - 1 )}} {Ge}^{2} \cdot {{BL}^{2} ( \frac{1}{4} )}^{2}}{{BL ( {2}^{b - 1} )}^{2} \frac{1}{12}} ) = 10 {log}_{10} ( Δ {l}_{0}^{2} {Ge}^{2} \cdot BL \cdot {2}^{- 4} ) .$$

Inserted for Δl₀=1/2¹² and Ge=0.9, it can be shown that the required block length for achieving 6 dB SNRk at the correlator output is 2²⁷. Before the modification introduced with FIG. 5, the required block length was 2³⁸. Thus, a significant saving in block length has been achieved.

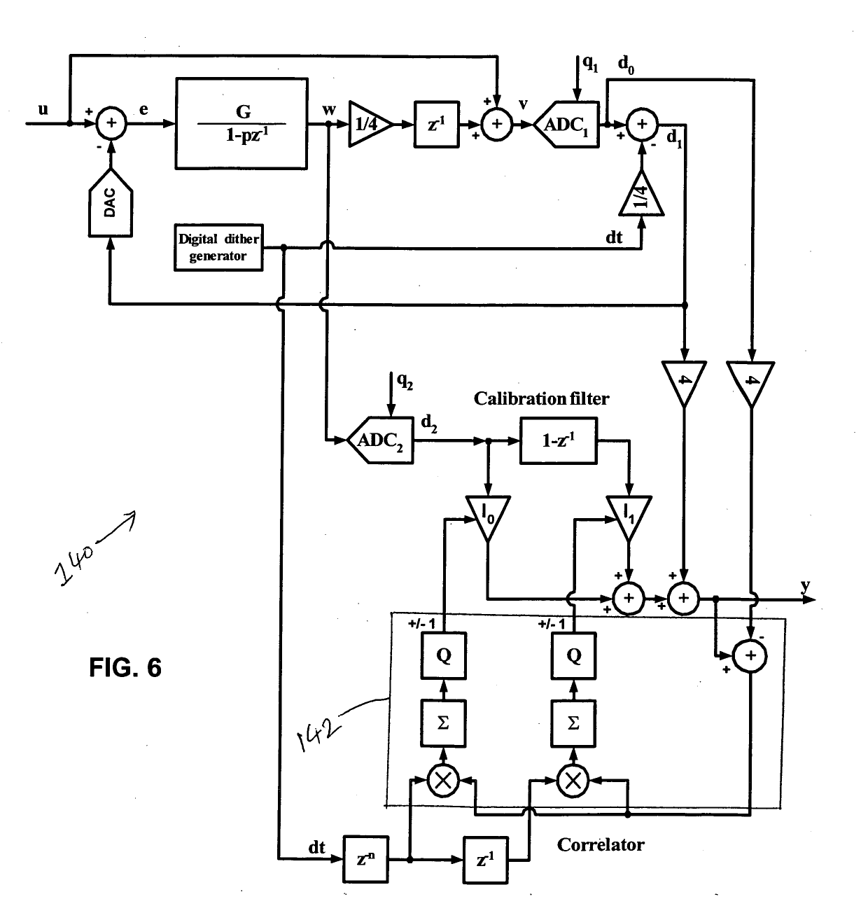

FIG. 6 illustrates a block diagram of a gain calibrated MASH ΔΣ ADC 140 with a correlator 142, where the structure of the correlator 142 has been modified such that instead of operating directly on the recombined output y of the ADC 140, a scaled version of the digital output d₀ from an ADSC of a first stage is subtracted from the output y of the ADC 140. This subtraction allows for significant reduction of the block length of the correlator 142, contributing in increased SNR and therefore accuracy of the correlator 142.

The above illustrations of pipelined and MASH ΔΣ ADCs using modified correlators also works for other high speed ADCs such as a pipelined ADC with 1.5 bit stages.

Although the foregoing text sets forth a detailed description of numerous different embodiments of the invention, it should be understood that the scope of the invention is defined by the words of the claims set forth at the end of this patent. The detailed description is to be construed as exemplary only and does not describe every possible embodiment of the invention because describing every possible embodiment would be impractical, if not impossible. Numerous alternative embodiments could be implemented, using either current technology or technology developed after the filing date of this patent, which would still fall within the scope of the claims defining the invention.

Thus, many modifications and variations may be made in the techniques and structures described and illustrated herein without departing from the spirit and scope of the present invention. Accordingly, it should be understood that the methods and apparatus described herein are illustrative only and are not limiting upon the scope of the invention.

What is claimed is:

1. A method of detecting trace of a test signal in a digital output signal of an analog-to-digital converter circuit, the analog-to-digital converter circuit converting an input signal to the digital output signal, the method comprising:
generating a coarse quantization signal from the input signal;
generating a difference signal based on the digital output signal and the coarse quantization signal;
multiplying the difference signal with the test signal to generate a product signal;
accumulating the product signal; and
detecting the sign at the output of the accumulator to determine the trace of the test signal.

2. A method of claim 1, wherein detecting the sign at the output of the accumulator further includes re-quantizing the accumulated signal to generate a one bit output signal.

3. A method of claim 1, wherein generating the coarse quantization signal from the input signal further comprises scaling a digital output of a first stage of the analog-to-digital converter circuit by a scaling factor.

4. A method of claim 3, wherein the scaling factor is equal to 2^{b-1} wherein b is a resolution of a backend stage of the analog-to-digital converter circuit.

5. A method of claim 4, further comprising inputting an output signal from the backend stage of the analog to digital converter circuit into a digital filter.

6. A method of claim 4, further comprising using the sign at the output of the accumulator to adjust the digital filter so as to remove the trace of the digital test signal from the output of the backend stage.

7. A method of claim 6, further comprising generating a sum of the scaled coarse quantization signal and an output of the calibration filter to generate the digital output signal.

8. A method of claim 1, wherein generating a difference signal includes generating a difference signal using at least one of (1) software; (2) hardware or (3) firmware.

9. An analog-to-digital converter system for converting an analog input signal to a digital output signal, the system comprising:
a first stage analog-to-digital converter circuit adapted to generate a residue signal based on the analog input signal;
a backend stage analog-to-digital converter circuit adapted to generate the digital output signal based on the residue signal;
a dither signal generator adapted to generate a dither signal to be inputted to the first stage analog-to-digital converter circuit;
a correlator circuit adapted to determine traces of the dither signal in the digital output signal; and
a calibration filter adapted to remove the traces of the dither signal from the digital output signal.

10. An analog-to-digital converter system of claim 9, further comprising a scaling circuit adapted to receive a quantized output signal from the first stage of the analog-to-digital circuit and to generate a scaled quantized signal to be input to the correlator circuit.

11. An analog-to-digital converter system of claim 9, wherein the scaling circuit is further adapted to scale the quantized output signal from the first stage by a scaling factor of 2^{b-1} wherein b is a resolution of a backend stage of the analog-to-digital converter circuit.

12. An analog-to-digital converter system of claim 10, wherein the correlator circuit further comprises:
a subtractor circuit adapted to subtract the scaled quantized signal from the digital output signal;
a multiplier circuit adapted to multiply the output of the subtractor circuit;
an accumulator circuit adapted to accumulate the output of the multiplier circuit; and
a re-quantizer circuit adapted to generate a 1 bit output signal based on the output of the accumulator circuit.

13. An analog-to-digital converter system of claim 10, further comprising a calibration circuit adapted to calibrate the output of the backend stage of the analog-to-digital converter circuit based on the output of the correlator circuit.

14. An analog-to-digital converter system of claim 13, wherein the first stage analog-to-digital converter circuit and the backend analog-to-digital converter circuit are ΔΣ analog to digital converter circuits.

15. An analog-to-digital converter system of claim 14, wherein the first stage analog-to-digital converter circuit and the backend analog-to-digital converter circuit are MASH ΔΣ analog to digital converter circuits.

16. An analog-to-digital converter system of claim 14, wherein the correlator circuit is implemented using at least one of: (1) software; (2) hardware or (3) firmware.

17. An analog-to-digital converter system for converting an analog input signal to a digital output signal, the system comprising:
a quantization signal generator module adapted to generate a coarse quantization signal from the input signal;
a differentiator module adapted to generate a difference signal based on the digital output signal and the coarse quantization signal;
a multiplier module adapted to multiply the difference signal with the test signal to generate a product signal;
an accumulator module adapted to accumulate the product signal; and
a detector module adapted to detect the sign at the output of the accumulator to determine the trace of the test signal.

18. An analog-to-digital converter system of claim 17, wherein the detector module is further adapted to re-quantize the accumulated signal to generate a one bit output signal.

19. An analog-to-digital converter system of claim 17, wherein the quantization signal generator module is further adapted to scale a digital output of a first stage of the analog-to-digital converter circuit by a scaling factor.

20. An analog-to-digital converter system of claim 19, wherein the scaling factor is equal to 2^{b-1} wherein b is a resolution of a backend stage of the analog-to-digital converter circuit.
